(19) United States
(12) Patent Application Publication
(10) Pub. No.: US 2026/0029293 A1
(43) Pub. Date: Jan. 29, 2026

(54) A SYSTEM AND A METHOD FOR DETECTING A FAULT IN A FLUID PATH OF A FLUID SYSTEM

(71) Applicants: NOVARES FRANCE, Vélizy-Villacoublay (FR); TRIBOSONICS LIMITED, Sheffield (GB)

(72) Inventors: Nicolas NIVARD, SIMENCOURT (FR); Julien BRODNIK, LOISON SOUS LENS (FR); Scott SCHWARTZ, JANESVILLE, WI (US); Philip HARPER, SHEFFIELD (GB); Hendrik JANNASCH, SHEFFIELD (GB); Ben WRIGHT, SHEFFIELD (GB)

(21) Appl. No.: 19/099,219

(22) PCT Filed: Jul. 19, 2023
(86) PCT No.: PCT/FR2023/051123

§ 371 Date: Jan. 28, 2025

(30) Foreign Application Priority Data
Jul. 29, 2022 (FR) 22/07870

(51) Int. Cl. G01M 3/18; G01R 31/66

(52) U.S. Cl. CPC G01M 3/182; G01R 31/66

(57) ABSTRACT

The present disclosure relates to a detection system for detecting a failure in a fluid path of a fluid system, the detection system including: at least one conduit including a conduit wall which defines a fluid path for the transfer of fluid; at least one connector connected to the at least one conduit, the at least one connector including two parts, respectively a female connector and a male connector, which are fixed together in a removable manner, the male connector being rigidly joined to the female connector in a connected state of the at least one connector, and the male connector being separated at least partially from the female connector in a partially or totally disconnected state of the at least one connector; at least one electrically conductive element forming an electrical signal pathway for an electrical signal that indicates a state of the at least one conduit and/or of the at least one connector; and an electrical terminal connected electrically to the at least one electrically conductive element, such that the first electrical signal is transmitted to the electrical terminal via the electrical signal pathway.

### CROSS REFERENCE TO RELATED APPLICATIONS

This application is a National Stage of PCT Application No. PCT/FR2023/051123 filed on Jul. 19, 2023, which claims priority to French Patent Application No. 22/07870 filed on Jul. 29, 2022, the contents each of which are incorporated herein by reference thereto.

### TECHNICAL FIELD

The present disclosure relates to systems and methods for detecting a failure in a fluid path of a fluid system. The present disclosure is particularly useful in the transportation industry.

### BACKGROUND

The ventilation systems of the crankcase remove unwanted gases from the crankcase of an internal combustion engine. The unwanted gases (also called «blow-by» gases) are gases that have leaked from the combustion chamber into the crankcase through the piston rings of the engine. The blow-by gases must be vented out of the crankcase, otherwise the gases can be combined with engine oil vapor in the crankcase to form sludge, and can cause the engine oil to be diluted with unburned fuel.

Early internal combustion engines used crankcase ventilation systems to vent blow-by gases to the atmosphere. Newer internal combustion engines use a positive crankcase ventilation (PCV) system to return blow-by gases to the combustion chamber for mixing with the air/fuel mixture and the combustion.

Currently, it is common for national regulators to require new vehicles to be equipped with a PCV system to prevent blow-by gas emissions into the atmosphere and thereby reduce vehicle emissions.

Typical PCV systems consist of a tube, a check valve or non-return flap, and a vacuum source (such as an intake manifold). National regulators often require that these PCV systems be monitored to detect any faults that would result in blow-by gases leaking. One current means of providing such monitoring is a gas pressure sensor inside the tube. A problem with this arrangement is that gas pressure sensors do not detect all possible fault modes and gas pressure sensors are often unreliable.

Recent changes in legislation require that a PCV system malfunction is detected when any conduit, for example a pipe, tube or conduit that carries crankcase vapors has a cut or break greater than or equal to the smallest internal cross-sectional area of that conduit.

An object of the present disclosure is to provide an alternative or improved detection system suitable for detecting a failure of a fluid path of a fluid system.

### BRIEF SUMMARY

The present disclosure provides a detection system and a method according to the appended claims.

In particular, the present disclosure relates to a detection system for detecting a failure in a fluid path of a fluid system, the detection system comprising:
at least one conduit comprising a conduit wall that defines a fluid path for fluid transfer;
at least one connector connected to the at least one conduit, said at least one connector comprising two parts, respectively a female connector and a male connector, removably fixed together, the male connector being secured to the female connector in a connected state of the at least one connector and the male connector being separated at least partially from the female connector in a partially or totally disconnected state of the at least one connector;
a retaining element slidably connected to the at least one connector, said retaining element being movable in an axial direction between a disengaged position, in which it allows relative axial movement between the female connector and the male connector, and an engaged position, in which it prevents relative axial movement between the female connector and the male connector;
a ring arranged between the female connector and the male connector, said ring being held in abutment against the male connector by means of at least one elastic return element exerting a thrust on the ring in a direction tending to move it away from the female connector, the at least one elastic return element being compressed when the at least one connector is in its connected state;
at least one electrically conductive element forming an electrical signal path for an electrical signal which indicates a state of the at least one conduit and/or the at least one connector; and,
an electrical terminal electrically connected to the at least one electrically conductive element such that the electrical signal is transmitted to the electrical terminal via the electrical signal path,

wherein said at least one electrically conductive element comprises at least one first electrically conductive segment secured to the at least one conduit, at least one second electrically conductive segment secured to the at least one connector, at least one third electrically conductive segment secured to the retaining element and at least one fourth electrically conductive segment secured to the ring, said at least one first electrically conductive segment being electrically connected to the at least one second electrically conductive segment, to the at least one third electrically conductive segment and to the at least one fourth electrically conductive segment in the connected state of the at least one connector and not being electrically connected to the at least one second electrically conductive segment and/or to the at least one third electrically conductive segment and/or to the at least one fourth electrically conductive segment in the partially or totally disconnected state of the at least one connector.

Thus configured, the detection system of the present disclosure will make it possible to detect a discontinuity in the signal path in the event of a failure of the conduit or a partial or total disconnection of the connector.

The detection system of the present disclosure may also comprise one or more of the following characteristics:
the at least one second electrically conductive segment comprises at least three separate portions, respectively a first portion and a second portion extending axially along an external wall of the female connector and a third portion extending circumferentially about said external wall.
the at least one third electrically conductive segment is in contact with the first and third portions of the at least one second electrically conductive segment in the engaged position of the retaining element and is not in contact with said third portion in the disengaged position of the retaining element.
the at least one fourth electrically conductive segment is in contact with the second and third portions of the at least one second electrically conductive segment in the connected state of the at least one connector and is not in contact with said second portion in the partially or totally disconnected state of the at least one connector.
the at least one elastic return element is integral with the ring and comprises two elastic blades of curved shape extending along two opposite sides of the ring, said elastic blades being deformed when the ring is compressed between the male connector and the female connector when the connector is in its connected state.
the ring comprises two straight tabs extending along two opposite sides of the ring, at least one of said straight tabs supporting at its free end the at least one fourth electrically conductive segment.
the detection system further comprises a processing unit for receiving the electrical signal and monitoring the electrical signal for an electrical characteristic that indicates a failure of the at least one conduit and/or a partial or total disconnection of the at least one connector respectively, the processing unit being configured to determine that a failure is present in the at least one conduit or that the at least one connector is totally or partially disconnected using the monitored electrical characteristic.
the electrical characteristic is one or more characteristics selected from the group consisting of: voltage, resistance, conductance, capacitance, inductance, frequency response, amplitude or transit time, or a change thereof.
the at least one first electrically conductive segment extends over the entire length of the at least one conduit.
the at least one first electrically conductive segment extends circumferentially around a surface of the conduit wall of the at least one conduit.
the at least one first electrically conductive segment is at least partially integrated in the conduit wall and/or provides an external or internal surface of the at least one conduit.
the at least one electrically conductive element comprises one or more conductive layer(s), strip(s), film(s), wire(s), braid(s) or a conductive polymer.
the at least one first electrically conductive segment secured to the at least one conduit is covered with a coating or a special material protecting the electrical signal from external electromagnetic influences present in a vehicle.

The present disclosure also relates to a vehicle comprising the detection system as defined above.

The present disclosure further relates to a method for detecting a state of a fluid system using the detection system as defined above, and comprising the steps of:
receiving an electrical signal from at least one electrically conductive element;
monitoring the electrical signal for an electrical characteristic that indicates a failure of the at least one conduit and/or a failure or a disconnection of the at least one connector; and
determining a failure in the fluid path of the fluid system based on the monitored electrical characteristic, wherein the electrical characteristic may be one or more characteristics selected from the group consisting of: voltage, resistance, conductance, capacitance, inductance, frequency response, amplitude or transit time, or a change thereof.

Those skilled in the art will understand that, unless mutually exclusive, a feature described in connection with any one of the aspects, examples or embodiments described herein may be applied to any other aspect, example, embodiment or feature. Furthermore, the description of any aspect, example or feature may be part of or the entirety of an embodiment of the present disclosure as defined by the claims. One of the examples described herein may be an example that represents the present disclosure defined by the claims and thus an embodiment of the present disclosure.

### BRIEF DESCRIPTION OF THE DRAWINGS

The present disclosure will now be described, by way of example only, with reference to the accompanying drawings, in which:

FIG. 1A is a perspective view of a detection system according to an embodiment of the present disclosure, the detection system being shown in a first state partially disconnected from the connector.

FIG. 1B is a view similar to FIG. 1a, the detection system being shown in a connected state from the connector.

FIG. 1C is a view similar to FIG. 1a, the detection system being shown in a second state partially disconnected from the connector.

FIG. 2A is a perspective view of the assembly formed by the female connector of the connector and the conduit of the detection system of FIG. 1a.

FIG. 2B is a perspective view of the second retaining element of the detection system of FIG. 1a.

FIG. 2C is a perspective view of the first retaining element of the detection system of FIG. 1a.

FIG. 2D is a perspective view of the ring of the detection system of FIG. 1a.

FIG. 3A is a sectional view along the section plane P1 of the detection system of FIG. 1b.

FIG. 3B is a sectional view along the section plane P2 of the detection system of FIG. 1b.

FIG. 3C is a sectional view along the section plane P3 of the assembly of FIG. 2a.

FIG. 3D is a cross-sectional view of a conduit variant that can equip the detection system of the present disclosure.

FIG. 4A is a lateral view of the assembly of FIG. 2a, in which some of the electrically conductive segments are shown when the connector is in its fully disconnected state.

FIG. 4B is a view similar to FIG. 4a, the electrically conductive segments being shown in the connected state of the connector.

FIG. 4C is a view similar to FIG. 4a, the electrically conductive segments being shown in the partially disconnected state of the connector.

FIG. 5A shows a schematic representation of a first configuration example of the detection system of the present disclosure, in particular, indicating a first configuration of an electrically conductive element and an electrical signal path.

FIG. 5B shows a schematic representation of a second configuration example of the detection system of the present disclosure, in particular, indicating a second configuration of an electrically conductive element and an electrical signal path.

FIG. 5C shows a schematic representation of a third configuration example of the detection system of the present disclosure, in particular, indicating a third configuration of an electrically conductive element and an electrical signal path.

FIG. 5D shows a schematic representation of a fourth configuration example of the detection system of the present disclosure, in particular, indicating a fourth configuration of an electrically conductive element and an electrical signal path.

FIG. 5E shows a schematic representation of a fifth configuration example of the detection system of the present disclosure, in particular, indicating a fifth configuration of an electrically conductive element and an electrical signal path.

FIG. 5F shows a schematic representation of a sixth configuration example of the detection system of the present disclosure, in particular, indicating a sixth configuration of an electrically conductive element and an electrical signal path.

FIG. 5G shows a schematic representation of a seventh configuration example of the detection system of the present disclosure, in particular, indicating a seventh configuration of an electrically conductive element and an electrical signal path.

FIG. 5H shows a schematic representation of an eighth configuration example of the detection system of the present disclosure, in particular, indicating an eighth configuration of an electrically conductive element and an electrical signal path.

FIG. 6 shows another schematic representation of a configuration example of the detection system of the present disclosure.

FIG. 7 shows a block diagram of an example of a bridge circuit used to detect a change in the resistance or the voltage caused by the deformation of a conductive element of a detection system according to the present disclosure.

FIG. 8 shows a block diagram of another example of a bridge circuit used to detect a change in the resistance or the voltage caused by the deformation of a conductive element of a detection system according to the present disclosure.

FIG. 9 shows a representation of a detection conduit of a detection system according to the present disclosure.

FIG. 10 shows an example of an assembly comprising multiple detection systems according to the present disclosure.

FIG. 11 is a flowchart indicating a method for operating a detection system according to the present disclosure.

### DETAILED DESCRIPTION

### General Arrangement

The present disclosure and the description refer to methods and apparatuses that are used to determine a state of a fluid path in a fluid system. The state may be one that may cause or create the risk of fluid leakage from the fluid system. The state may be a failure in a fluid path defined by one or more conduits or connectors.

The failure may be mechanical and may comprise a deformation, damage or cut of the conduit(s) or connector(s). The deformation/damage may include any abnormal shape or thickness of a conduit or conduit wall that is outside of normal operating parameters. The deformation/damage may include a change in a cross-section of the conduit or conduit wall at one or more locations caused, for example, by a bulge or other distortion in the conduit wall resulting from a local weakness. The deformation/damage may include a break in a conduit wall that would result in a loss of fluid. The break may be an opening such as a hole, a crack, a rupture or a partial or total cut or disjunction of the conduit. The failure may be a deformation, a damage, the partial or total disconnection or the break in a wall of one or more connector(s) in the fluid system.

The failure may result in an opening in the fluid path that is at least as large as the smallest cross-sectional area of the fluid path defined in the fluid system and/or conduit and connectors that are monitored by the detection system.

The failure may also result in a small hole in the range of a few mm in the conduit carrying the fluid.

Note that the term «fluid» may refer to a liquid, gas or vapor.

The present disclosure provides a detection system for detecting a failure in a fluid path of the fluid system, the fluid system comprising one or more conduits and one or more connectors for coupling or delimiting the conduits in the fluid system, the detection system comprising: a conduit connected to a connector and comprising a wall that defines a fluid path for fluid transfer and an electrically conductive element that forms an electrical signal path for a first electrical signal; and, a processing unit configured to receive the first electrical signal and monitor the electrical signal for an electrical characteristic that indicates a failure of the conduit and/or a disconnection of the connector. For example, the processing unit may be configured to determine that a failure is present in the conduit or that the connector is totally or partially disconnected from the conduit using the at least one monitored electrical characteristic.

In an embodiment, the electrical signal may be a voltage that is applied to the at least one electrically conductive element. The monitoring of the voltage, for example the voltage magnitude, can provide information about the resistance or the voltage of the electrically conductive element which may change in the event of a conduit failure and/or partial or total disconnection of the connector.

The detection system may be provided as part of a fluid system in which a gas, liquid or vapor is transported from one location to another in, for example, a vehicle. The fluid system may be hydraulic or pneumatic. The fluid may be a coolant, lubricant, air, oil, fuel or any other gas, liquid or vapor. Typical uses of the present disclosure may include a crankcase ventilation system as described in the background section, a battery pack cooling system, an electric motor cooling system, a lubrication system, a fuel system or a hydrogen vehicle cooling system. The system may be part of a conventional internal combustion engine, a hybrid vehicle, an electric vehicle, a hydrogen or fuel cell vehicle.

It is noted that the detection system may be used in other applications outside of automotive, such as aerospace or marine vessels, or elsewhere. The detection system may be used to detect leaks or mechanical faults during use of a system and/or may be used to test the fluid system assembly to ensure that the system is leak-free prior to each use or after initial assembly.

The detection system may be part of a monitoring system such as an engine health monitoring system or an on-board diagnostic system. Accordingly, the fluid detection system may monitor the fluid system for leaks, or a risk of leaks, and provide data or a signal indicating a state of the fluid system to an overall monitoring system. The data and/or signal captured or determined by the detection system may be used to provide a user with a status of the fluid system.

For example, the detection system may provide a signal indicating that there is a possible leak and the location of the leak.

### Conduit

The conduit may be configured to transfer fluid from a first location at a first end to a second location at a second end along a fluid path as is well known in the art. The conduit may comprise a first end and a second end and may be consisting of a single portion or multiple portions connected together using suitable connections. The sections of the conduit may be connected by suitable connectors, such as the detected connectors described herein, or they may be joined together by adhesion, mechanical retention, or welding, for example.

The connectors may be two-part connectors, such as a male/female connector in which a first male connector is sealingly inserted into a second female connector. The connectors may comprise, for example, compression connectors or push-fit connectors having an interference fit and/or one or more sealing elements as is well known in the prior art.

The conduit may be rigid or flexible and may have any desired length or cross-section. In many embodiments, the cross-section of the conduit will be circular, with the conduit being generally cylindrical. The conduit may comprise a wall that defines a fluid path for the fluid transfer.

### Connectors

The conduit may be terminated by or include one or more connectors that join one end of the conduit to another element in the fluid system, or join two portions of the conduit together. The connector may be referred to as a fluid connector as it connects the fluid path, however, the fluid connector may also include electrical elements forming part of the electrical signal path and/or an electrically conductive element used to transmit electrical signals to the electrical terminal. As noted above, the connectors may comprise, for example, compression connectors or push-fit connectors having an interference fit and/or one or more sealing elements as is well known in the prior art.

There may be a plurality of connectors. Each of the plurality of connectors may be associated with a different conduit. The plurality of conduits may be arranged in series, in parallel or in a radial arrangement. The plurality of conduits may belong to separate systems that may or may not relate to the same fluid system. Thus, there may be a plurality of conduits and/or connectors that are electrically connected to a common electrical terminal and/or processing unit.

Providing a single electrical terminal and/or processing unit for a number of detection conduits may reduce the infrastructure required to implement the detection system.

The electrical connection between the conduit sections and/or the connectors may be provided by a conductive connection having a low resistance interface to allow an efficient transmission of all electrical signals. The electrical connection may include multiple sets of connectors to provide distinct electrical paths. As noted above, the paths may include one or more signal paths and one or more return paths.

The electrical connection may include one or more coils for inductive coupling through the connector. In some embodiments, the electrical connection may be provided by a conductive epoxy or the like in the connecting interface. Other mechanical elements may be included to help bridge the connection, such as conventional electrical contacts that contact an electrically conductive element within or on the conduit, such as an overbraid.

### Electrically Conductive Element

As noted above, the conduit and/or a connector connected thereto may be configured to transmit an electrical signal to an electrical terminal. The electrical signal will be transmitted along one or more conductive electrical signal paths provided within, for example as part of, the conduit and/or the connector. Accordingly, the conduit and/or the connector may comprise at least one electrically conductive element formed of one or more electrically conductive segments embedded within, on or in a wall of the conduit or the connector. The one or more electrically conductive element segments may comprise multiple distinct electrical signal paths as described in more detail below. Each electrically conductive segment may comprise one or more conductive layer(s), film(s), wire(s), braid(s), a conductive polymer or a conductive ink printed on the external wall of the conduit. Each electrically conductive segment may extend over the entire length of the conduit from a first end to a second end. Each electrically conductive segment may also extend circumferentially around the conduit wall so as to at least partially or totally surround the conduit. Thus, each electrically conductive segment may comprise one or more sleeves, tubes, or layers within, on, or in the conduit wall. Each electrically conductive segment may also extend circumferentially around the conduit wall so as to at least partially or totally surround the conduit. Thus, each electrically conductive segment may comprise one or more sleeves, tubes, or layers within, on, or in the conduit wall. Each electrically conductive segment may be at least partially embedded in the conduit wall and/or may provide an internal surface of the conduit and/or cover and/or overbraid the conduit.

Each electrically conductive segment may comprise a conductive polymer or a metallic conductive element. The conductive polymer may comprise multiple conductive layers or conductive bands that are part of the conduit wall. The different conductive layers or bands may be used to provide different signal paths that are configured to carry different electrical signals. The electrically conductive segments may be wires embedded in the conduit wall and may be coextruded. The wires may be overbraided. An electrically conductive segment may also be consisting of a metal tape wrapped around the conduit.

### Electrical Characteristics of the Conduit

Each electrically conductive segment that is secured to the conduit may define one or more electrical characteristics of the conduit that may be monitored by the detection system to determine whether the one or more electrical characteristics change over time. A change in the one or more electrical characteristics may indicate a failure of the conduit. The failure may be a change in the shape of the conduit such as an expansion (for example a bulge caused by a fault of the structural integrity of the conduit wall) or a compression (for example an unintended or unwanted compression), or a rupture in which an opening in the conduit wall occurs.

The failure may comprise a total rupture or cut of two portions of the conduit at a connector or in a continuous length of the conduit wall.

Monitoring the electrical characteristics of the conduit may allow the fluid system to detect a total break in the conduit resulting in a total loss of an electrical signal.

Alternatively or additionally, monitoring the conduit may allow detecting damages by a loss of signal in one or more of the signal paths or a change in an electrical characteristic (other than a loss of signal).

The at least one electrical characteristic may be one or more characteristics selected from the group consisting of: resistance, voltage, conductance, capacitance, inductance or amplitude, for example. However, other characteristics, known in the prior art, may be used in certain embodiments.

The electrical characteristic may also be monitored to detect a change in the characteristic over time, rather than only monitoring the instantaneous or absolute value of that characteristic.

### Electrical Terminal

The electrical terminal may be electrically connected to an electrically conductive segment that is secured to the conduit to provide the electrical signal carried by that segment. The electrical terminal may provide a connection point for connecting the electrically conductive segment to a monitoring system via external wiring or a wireless link. The external wiring may receive the electrical signals received by the electrical terminal and/or may send a signal that indicates the state of the conduit to the monitoring system.

The electrical terminal may comprise a housing in which one or more electrical terminals or electrical connections are provided as is well known in the prior art.

The electrical terminal may be mounted to a connector of the fluid system or a surrounding structure. When the electrical terminal is mounted to a connector, the connector may be referred to as a terminal connector or an interface connector.

### Processing Unit

In some embodiments, the electrical terminal may comprise a processing unit configured to receive the electrical signal carried by the electrically conductive element segment that is secured to the conduit. Additionally or alternatively, the processing unit may be configured to monitor at least one electrical characteristic of the conduit. Additionally or alternatively, the processing unit may be configured to determine a state of the conduit or a connector mounted to the conduit. In some embodiments, the processing unit may be located remotely from the electrical terminal. Thus, the processing unit may be part of a different or larger monitoring system such as an on-board diagnostic system of a vehicle (of the ECU type). Thus, the electrical signal received by the electrical terminal may be transmitted to the processing unit via the electrical terminal, or the electrical terminal may include the processing unit that outputs either an alert or a signal that indicates the state of the conduit or the connector.

The processing unit may be configured to determine a leak state in the conduit using the at least one monitored electrical characteristic. The leak state may be determined from electrical signals received by the electrical terminal. The leak state may correspond to a breakdown of the conduit or to a (total or partial) disconnection of one or more connectors.

The processing unit may be configured to process one or more electrical signals and/or one or more electrical characteristics.

In addition to electrically conductive segments secured to the conduit, the detection system may use external conductive paths such as, for example, a vehicle chassis for a return path.

In various embodiments, the processing unit may comprise: control circuits; and/or processor circuits; and/or at least one application specific integrated circuit (ASIC); and/or at least one field programmable gate array (FPGA); and/or single or multiprocessor architectures; and/or sequential/parallel architectures; and/or at least one programmable logic controller (PLC); and/or at least one microprocessor; and/or at least one microcontroller; and/or a central processing unit (CPU) for executing the methods. The processing unit may be executed in hardware or software, for example.

The external connector may also comprise one or more memories. The one or more memories may comprise a non-transitory computer-readable storage medium comprising computer-readable instructions that, when read by the processing unit, configure the processing unit to perform the methods described herein. The computer-readable instructions may comprise executable code relating to monitoring or determining or categorizing the conduit or a leak, for example.

The one or more memories may comprise: volatile memory, for example, one or more dynamic random access memory (DRAM) modules and/or static random access memory (SRAM) modules; and/or non-volatile memory, for example, one or more read-only memory (ROM) modules, which may comprise, for example, a Flash memory and/or another electrically erasable programmable read-only memory (EEPROM) device.

### Operation

As noted above, the operation of the detection system may comprise receiving a signal from an electrically conductive element formed of one or more electrically conductive segments disposed in the conduit and/or in a connector mounted to the conduit. The signal may be monitored to determine an electrical characteristic of the signal (which corresponds to an electrical state or characteristic of the conduit or connector) or a change in the signal. The change in the signal may be a change in amplitude or a total loss of signal due to failure or cut of the conduit or partial or total disconnection of the connector. In some embodiments, the frequency content and/or phase and/or timing of the signal may change. In some embodiments, electrical signals may be injected into the conduit and monitored for a change. For example, a voltage may be applied to one or more electrically conductive elements and the voltage is monitored to determine whether the electrical characteristics of the conduit have changed.

When a change in an electrical characteristic is detected, the reason for the change may be determined and an assessment made as to whether this indicates a leak in the system or, in some embodiments, whether the system has degraded such that the risk of leakage may increase.

An appropriate alert may be provided to a user of the system or the machine in which the system is installed, such as a vehicle, so that appropriate action may be taken.

### SPECIFIC EMBODIMENTS

A number of specific embodiments in relation to the drawings are described below. It will be appreciated that the features of the specific embodiments may be used interchangeably where technically possible to provide intermediate embodiments.

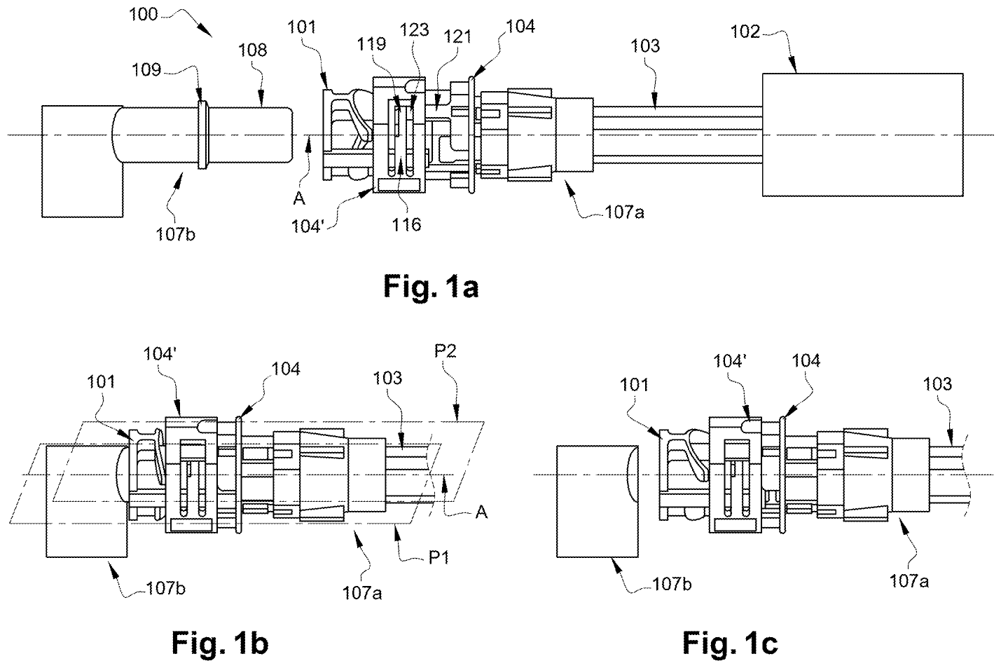

Referring to FIGS. 1a to 1c, a detection system 100 according to the present disclosure is provided, which system is suitable for use as a positive crankcase ventilation (PCV) device. The detection system includes an electrical terminal 102 (which may also be referred to as a communication interface), a conduit 103, comprising a conduit wall 106 which defines a fluid path for fluid transfer, and a connector connected to the conduit 103, said connector comprising two parts, respectively a female connector 107a and a male connector 107b, removably secured together. The male connector 107b is secured to the female connector 107a in a connected state of the connector, shown in FIG. 1b, and the male connector 107b is at least partially separated from the female connector 107a in a partially disconnected state, as shown in FIG. 1c, or fully disconnected, as shown in FIG. 1a, of the connector.

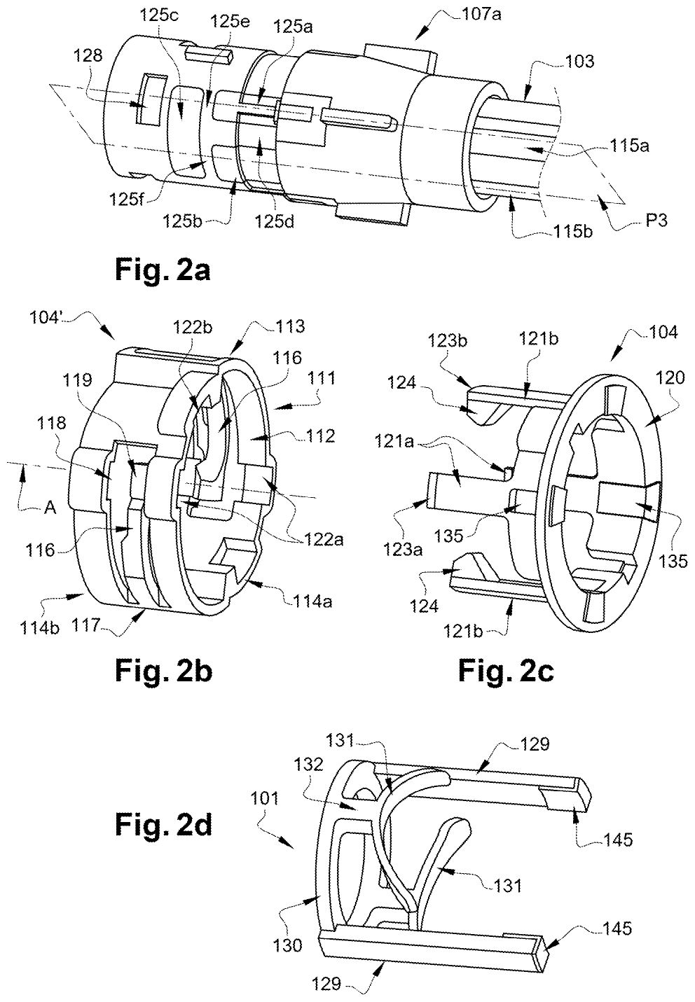

The detection system 100 moreover comprises a first retaining element 104, shown in FIG. 2c, slidably connected to the female connector 107a, said first retaining element 104 being able to move in an axial direction A between a disengaged position, shown in FIG. 1a, in which it allows a relative axial movement between the female connector 107a and the male connector 107b, and an engaged position, shown in FIG. 1b, in which it prevents a relative axial movement between the female connector 107a and the male connector 107b.

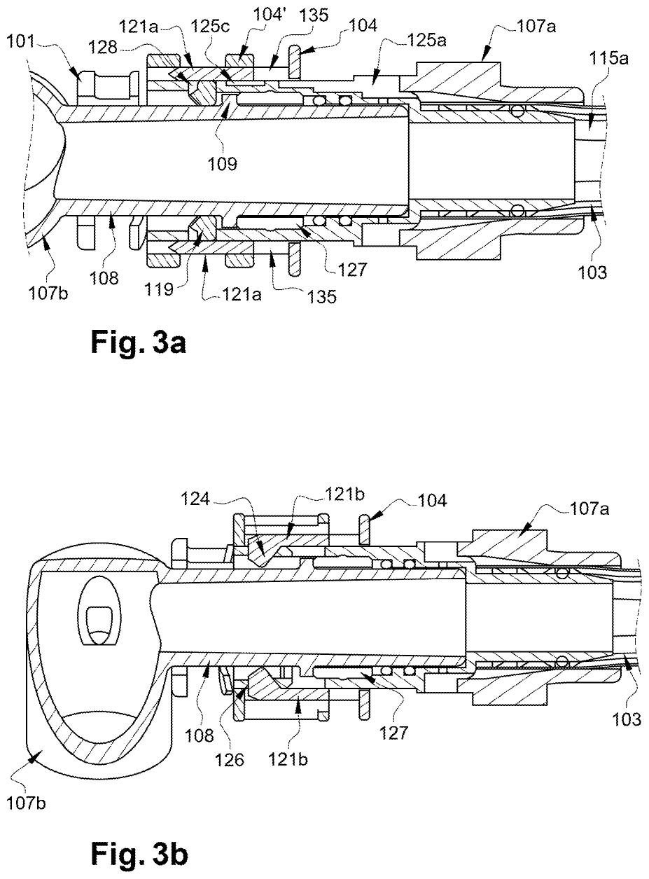

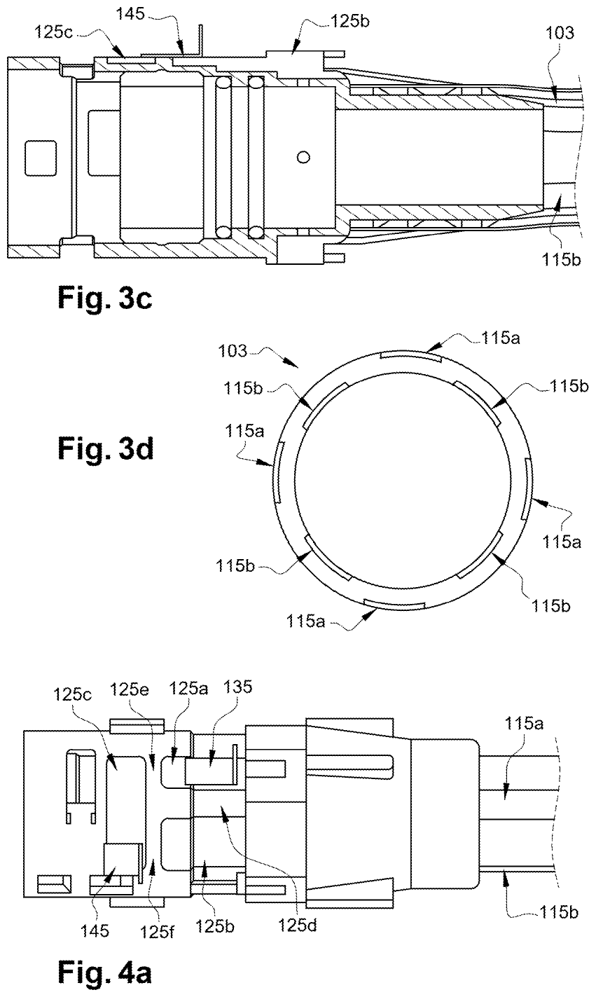

To this end, the first retaining element 104 cooperates with a second retaining element 104′, shown in FIG. 2b. This second retaining element 104′ has an annular retaining wall 111 with internal 112 and external 113 surfaces extending along the axial direction A between an open proximal end 114a and an open distal end 114b. The internal surface 112 is configured to at least partially receive a tubular end 108 of the male connector 107b in the connected state of the connector (see FIG. 1b). The retaining wall 111 further comprises at least one, and as shown in FIG. 2b, a pair of locking fingers 116 extending radially inward from the internal surface 112, the locking fingers 116 being configured to come into locked engagement with an annular collar 109 extending radially outward from the cylindrical external surface of the tubular end 108 of the male connector 107b when the connector is in its connected state, as shown in FIG. 3a. Thus positioned, the locking fingers 116 allow a pre-retaining of the male connector 107b.

Each locking finger 116 is substantially detached from the retaining wall 111 from a fixed end 117, and is surrounded by a respective opening 118 in the retaining wall 111. Each locking finger 116 will thus be able to pivot about its fixed end 117 from a first extreme position (shown in FIG. 3a), in which the locking finger 116 extends radially inward, its free end 119 abutting the cylindrical external surface of the tubular end 108 of the male connector 107b, to a second extreme position (not shown), in which its free end 119 is slightly radially spaced from the cylindrical external surface of the tubular end 108 of the male connector 107b. In the first extreme position, the free end 119 is axially aligned with the collar 109, thus preventing a relative axial movement between the male connector 107b and the female connector 107a in the direction of a disconnection of the male connector 107b when the collar 109 abuts against the free end 119. The locking fingers 116 are held in their first extreme position by the first retaining element 104. This in fact comprises two first locking tabs 121a extending axially from an annular end ring 120, the first locking tabs 121a being diametrically opposed to each other around the circumference of the end ring 120. When the first and second retaining elements 104, 104 are mounted on the female connector 107a, the first locking tabs 121a are axially aligned with first shapes in hollows 122a of the second retaining element 104 which extend radially outwardly from the internal surface 112. As shown in FIGS. 2b and 2c, each first locking tab 121a is mated with a pair of first hollow shapes 122a which are aligned in the axial direction A, said first hollow shapes 122a being arranged on either side of an opening 118 while being substantially adjacent to the free end 119 of one of the locking fingers 116.

In the totally disconnected state of the connector shown in FIG. 1a, the first retaining element 104 is arranged relative to the second retaining element 104 such that the first locking tabs 121a are engaged in only one first hollow shape 122a, their free end 123a adjoining the free end 119 of one of the locking fingers 116 and being positioned radially outwardly relative to said free end 119. As a result, when the first retaining element 104 is moved axially towards the second retaining element 104′, the first locking tabs 121a come to position themselves around the free ends 119 of the locking fingers 116, thus causing the locking fingers 116 to pivot in a direction tending to bring them radially closer to the center of the second retaining element 104′. Thus, after having inserted the tubular end 108 of the male connector 107b inside a central cavity of the female connector 107a until the collar 109 abuts against an internal ring 127 fixed inside the female connector 107a, as shown in FIG. 3a, the user will axially move the first retaining element 104 towards the second retaining element 104′, so as to cause the pivoting of the locking fingers 116. The free ends 119 of said locking fingers 116 which face through openings 128 of the female connector 107a (as shown in FIG. 2a) abut radially against the tubular end 108 of the male connector 107b, thus resulting in the connected state of the connector shown in FIG. 1b. The locking fingers 116 are blocked in this position by the first locking tabs 121a.

The first retaining element 104 further includes two second locking tabs 121b extending axially from the annular end ring 120, the second locking tabs 121b being diametrically opposed to each other around the circumference of the end ring 120. When the first and second retaining elements 104, 104′ are mounted on the female connector 107a, the second locking tabs 121b are axially aligned with second recessed shapes 122b of the second retaining element 104′ which extend radially outwardly from the internal surface 112. As shown in FIG. 2b, each second locking tab 121b is provided at its free end 123b with a substantially pyramidal-shaped protrusion 124 projecting radially inwards. As shown in FIG. 3b, this protrusion 124 is capable of being received inside a slot 126 of the female connector 107a in the totally connected state of the connector, thus preventing the axial displacement of the first retaining element 104 from its engaged position to its disengaged position.

The detection system 100 further comprises a ring 101 which is arranged between the male connector 107b and the female connector 107a. This ring 101, shown in FIG. 2d, comprises two straight tabs 129 extending axially from an annular end ring 130, the straight tabs 129 being diametrically opposed to each other along the circumference of the end ring 130. The ring 101 further comprises two elastic blades 131 of curved shape connected axially to the end ring 130 by means of crosspieces 132. The elastic blades 131 are configured to be deformed when the ring 101 is compressed between the male connector 107b and the female connector 107a in the connected state of the connector, as illustrated in FIG. 1b. These elastic blades 131, due to their elasticity, exert a thrust on the ring 101 in a direction tending to move it away from the female connector 107a. Therefore, when the connector is in its totally disconnected state, as in FIG. 1a, or partially disconnected, as in FIG. 1c, due to a break of the male connector 107b, the ring 101 returns to its initial uncompressed state shown in FIG. 2d.

In another configuration of the present disclosure, the elastic blades 131 may be formed by separate parts added in metal material, such as leaf or spiral springs.

As explained above, the detection of a failure in the conduit 103 and/or a partial or total disconnection of the connector is ensured in the detection system 100 by the use of electrically conductive segments forming an electrical signal path for an electrical signal that indicates a state of the conduit 103 and/or the connector. In the embodiment of FIG. 1a, and as shown in FIGS. 2a, 3a and 3c, the electrically conductive segments are integrated respectively in the conduit 103, in the female connector 107a, in the first retaining element 104 and in the ring 101.

The electrical signal path is thus defined firstly by a first electrically conductive segment 115a and a second electrically conductive segment 115b extending axially along the external periphery of the conduit 103. These first and second electrically conductive segments 115a, 115b are electrically connected to the electrical terminal 102 so that the electrical signal carried along the electrical signal path is transmitted to the electrical terminal 102.

It will be possible, in other embodiments of the present disclosure, to integrate a plurality of first and second electrically conductive segments 115a and 115b along the conduit 103, said electrically conductive segments 115a, 115b which can be arranged indifferently along the internal periphery and/or along the external periphery of the conduit 103, and/or be at least partially integrated into the wall 106 of the conduit 103. The electrically conductive segments 115a, 115b can advantageously be distributed around the circumference of the conduit 103.

A possible configuration is thus shown in FIG. 3d. In this configuration, four pairs of first and second electrically conductive segments 115a, 115b are equidistantly distributed around the circumference of the conduit 103, the first electrically conductive segment 115a of each of the pairs being arranged along the external periphery of the conduit 103 and the second electrically conductive segment 115b of each of the pairs being arranged along the internal periphery of the conduit 103. Each pair of electrically conductive segments 115a, 115b will advantageously be electrically connected to an adjacent pair of electrically conductive segments 115a, 115b by means of an electrical connector (not shown). The electrical signal path defined by these pairs of electrically conductive segments 115a, 115b will thus make it possible to detect failures over almost the entire conduit 103 due to its successive back and forth movements from one end of the conduit 103 to the other.

In a variant of the present disclosure, the first and second electrically conductive segments 115a, 115b may advantageously be covered with a coating or a special material protecting the electrical signal from external electromagnetic influences present in a vehicle.

The electrical signal path is defined secondly by third, fourth and fifth electrically conductive segments 125a, 125b and 125c. The third and fourth electrically conductive segments 125a and 125b extend axially along the external periphery of the female connector 107a, by being spaced from each other in the circumferential direction by a non-conductive portion 125d. The fifth electrically conductive segment 125c extends partially around the circumference of the female connector 107a while being axially spaced from the third and fourth electrically conductive segments 125a, 125b by non-conductive portions 125e and 125f respectively. As shown in FIGS. 2a, 3a and 3c, the third and fourth electrically conductive segments 125a and 125b are electrically connected to the first and second electrically conductive segments 115a and 115b respectively.

The electrical signal path is finally defined by a plurality of sixth and seventh electrically conductive segments 135 and 145 which are secured to the first and second retaining elements 104, 104′ respectively. As shown in FIG. 2c, the sixth electrically conductive segments 135 each have a right-angle shape and extend at least partially around the internal periphery of the end ring 120 of the first retaining element 104. The seventh electrically conductive segments 145 also have a right-angle shape and are arranged at the free ends of the straight tabs 129 of the ring 101, as shown in FIG. 2d.

The respective position of the sixth and seventh electrically conductive segments 135, 145 relative to the third, fourth and fifth electrically conductive segments 125a, 125b, 125c will vary depending on the respective position of the retaining elements 104, 104′ relative to the female connector 107a,

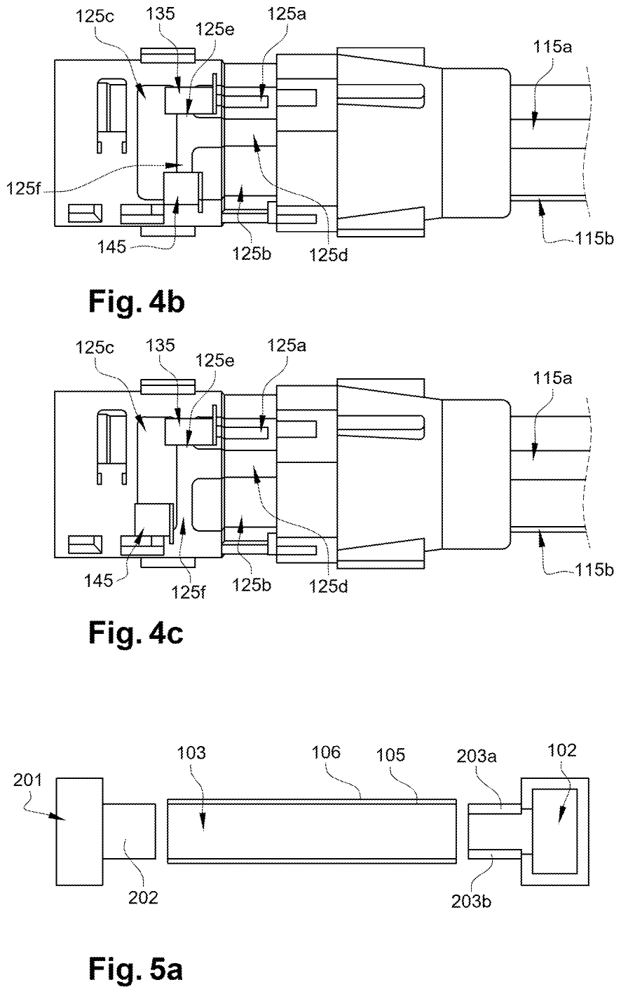

Therefore, when the first retaining element 104 and the ring 101 are mounted on the female connector 107a in the position shown in FIG. 1a, at least one of the sixth electrically conductive segments 135 is radially aligned with and in contact with the third electrically conductive segment 125a and at least one of the seventh electrically conductive segments 145 is radially aligned with and in contact with the fifth electrically conductive segment 125c, as shown in FIG. 4a.

In this position, the sixth and seventh electrically conductive segments do not allow an electrical connection to be established between the third, fourth and fifth electrically conductive segments 125a, 125b and 125c. The electrical terminal 102 will therefore detect a discontinuity in the electrical signal path. This discontinuity may be analyzed by a processing unit in communication with, or in interface with, the electrical terminal 102. The processing unit may thus be configured to provide a user (for example the driver of the vehicle or a mechanic) with an alert relating to the totally disconnected state of the connector.

When the first retaining element 104 and the ring 101 are mounted on the female connector 107a in the position shown in FIG. 1b, at least one of the sixth electrically conductive segments 135 is radially aligned with a non-conductive portion 125e and is in contact with the third electrically conductive segment 125a and the fifth electrically conductive segment 125c and at least one of the seventh electrically conductive segments 145 is radially aligned with a non-conductive portion 125f and is in contact with the fourth electrically conductive segment 125b and the fifth electrically conductive segment 125c, as shown in FIG. 4b. In this position, the sixth and seventh electrically conductive segments allow an electrical connection to be established between the third, fourth and fifth electrically conductive segments 125a, 125b and 125c. The electrical terminal 102 will therefore detect continuity in the electrical signal path. This continuity can be analyzed by the processing unit. The processing unit can thus be configured to provide a user with information relating to the connected state of the connector.

When the first retaining element 104 and the ring 101 are mounted on the female connector 107a in the position shown in FIG. 1c, at least one of the sixth electrically conductive segments 135 is radially aligned with a non-conductive portion 125e and is in contact with the third electrically conductive segment 125a and the fifth electrically conductive segment 125c and at least one of the seventh electrically conductive segments 145 is radially aligned with and is in contact with the fifth electrically conductive segment 125c, as shown in FIG. 4c. In this position, the sixth and seventh electrically conductive segments provide an electrical connection between the third and fifth electrically conductive segments 125a and 125c, but not between the fourth and fifth electrically conductive segments 125b and 125c. The electrical terminal 102 will therefore detect a discontinuity in the electrical signal path. This discontinuity may be analyzed by the processing unit. The processing unit may thus be configured to provide a user with information relating to the partially disconnected state of the connector.

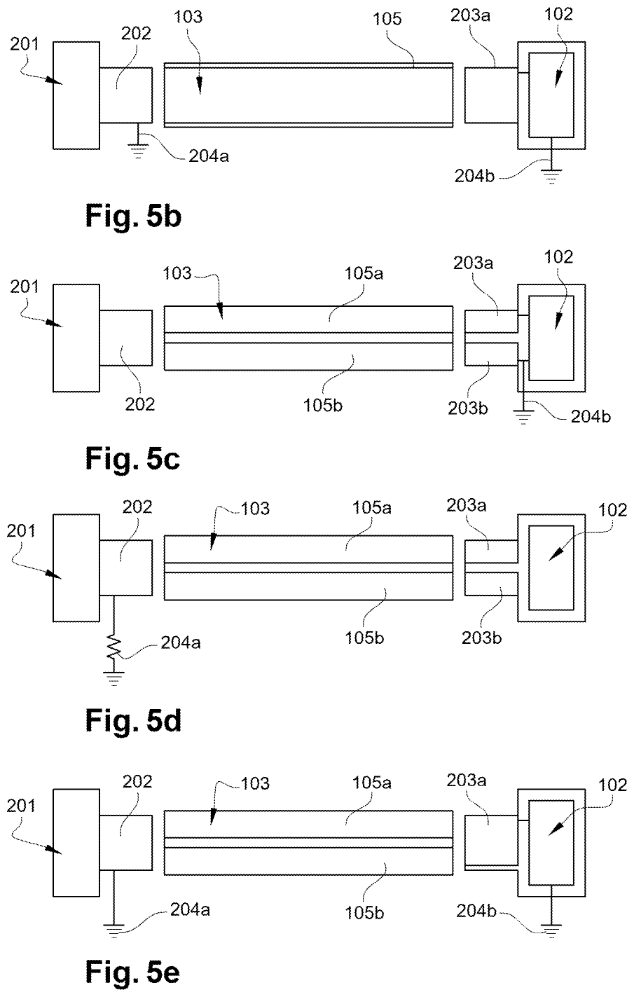

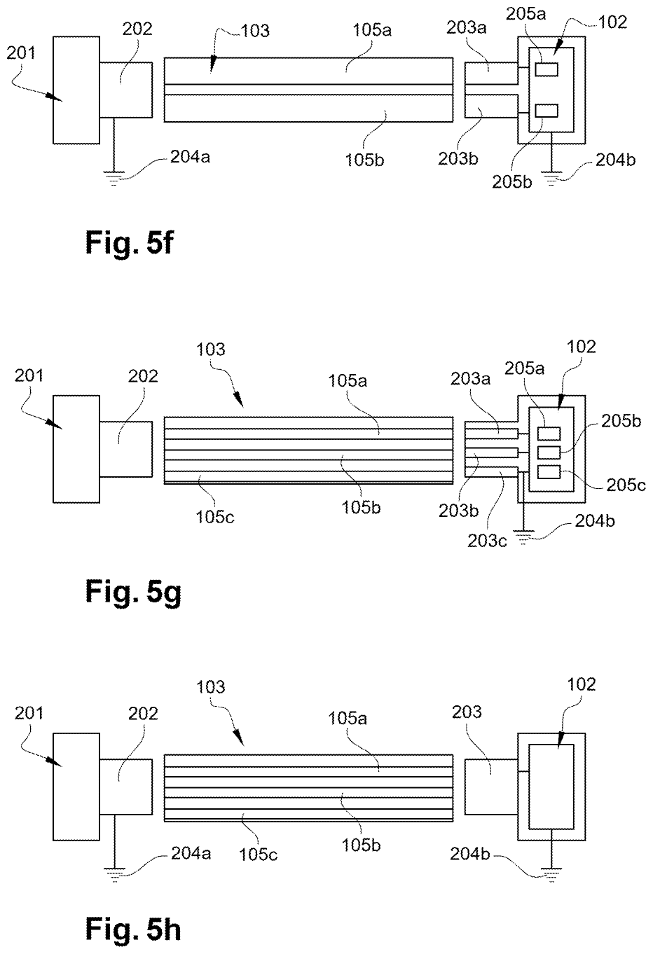

Various possible configurations of the detection system as described with reference to FIGS. 1a to 4c will now be described with reference to FIGS. 5a to 5h.

With reference to FIG. 5a, the electrically conductive element 105 is in the form of an internal layer, for example a coating, of a conduit 103. The internal layer may be exposed to or directly in contact with the fluid inside the conduit 103 during the use, for example. The electrical terminal 102 may be located at one end of the conduit 103 and may be electrically coupled to the electrically conductive element 105 by two local conductive regions 203a, 203b.

The detection system may comprise a remote connector 201 (which may be equivalent to the connector of FIG. 1a), which is located at an opposite end of the conduit 103 relative to the electrical terminal 102 comprising a processing unit. The remote connector 201 may comprise a remote conductive region 202. In such an arrangement, the electrical signal path is formed by the two local conductive regions 203a, 203b, the electrically conductive element 105 and the remote conductive region 202. The remote conductive region 202 may include a ground connection (not shown) to provide static discharge, as is known in the prior art.

When there is a rupture in the conduit wall 106, or a cut between the remote connector 201 and the conduit 103 or between the electrical terminal 102 and the conduit 103, then there is a change in the signal path causing a change in one or more electrical characteristics that can be detected by the electrical terminal 102. In the particular configurations of FIGS. 5a-h, the electrical terminal 102 may include a voltage or resistance monitoring device and the detection of a rupture in the conduit wall 106 or a cut may be based on a measurement of a change in voltage or resistance across the signal path. The configuration of FIG. 2a has been shown to be more effective in detecting ruptures that are located closer to the electrical terminal 102, as compared to those that are located further from the electrical terminal 102.

Referring to FIG. 5b, an alternative configuration to FIG. 5a is shown with reference numerals corresponding to the same features described above. There is a single local conductive region 203a connected to the electrically conductive element 105, which is in the form of an internal conductive layer. There are two ground connections 204a and 204b connected to the remote conductive region 202 and the electrical terminal 102 respectively.

The signal path is formed by the local conductive region 203a, the electrically conductive element 105, the remote conductive region 202, and the region between the ground connections 204a and 204b. The signal path can be considered to comprise a detection portion (in this case, from electrical terminal 102 to ground connection 204a), and a return portion (in this case, from ground connection 204a to ground connection 204b).

As used herein, the term «detection portion» may refer to a portion of the signal path extending through the conduit 103 to an end of the conduit 103 opposite the electrical terminal 102. The term «return portion» may refer to a portion of the signal path «returning» to the electrical terminal 102 from the end of the conduit 103 opposite the electrical terminal 102. The «return portion» of the signal path may or may not be configured to provide detection capability. In the example of FIG. 5b, the return portion of the signal path is between the ground connections 204a, 204b, and is, therefore, typically on grounded elements such as a chassis of a vehicle. A particular advantage of the configuration of FIG. 5b is that ruptures along the entire length of the conduit 103, or the cuts at each end of the conduit 103, are detectable substantially equally.

Referring to FIG. 5c, an alternative configuration to FIG. 5a is shown with reference numerals corresponding to the same features described above. The electrically conductive element comprises two separate segments 105a and 105b. The electrical terminal 102 comprises two local conductive regions 203a, 203b for the connection to the corresponding two separate segments 105a, 105b. The signal path is formed by the circuit provided by the local conductive region 203a, the electrically conductive element 105a, the remote conductive region 202, the electrically conductive element 105b and the local conductive region 203b. There is a single ground connection 204b connected to the interface connector 102. In this configuration, the detection and return portions of the signal path are both located along the conduit 103, and there is no need for a chassis ground connection for the return portion according to the configuration of FIG. 5b. The segments 105a, 105b may be segmented internal conductive coatings applied to an internal surface of the conduit 103.

The configuration of FIG. 5d is similar to that of FIG. 5c with the inclusion of a ground connection 204a connected to the remote conductive region 202. In this configuration, the ground connection 204a includes a grounding resistor to ensure that the ground connection does not interfere with the return portion of the signal path. The ground connection 204a at this location provides a static discharge from the remote conductive region 202.

The configuration of FIG. 5e is similar to that of FIG. 5b, except that the electrically conductive element comprises two segments 105a, 105b in the form of multiple layers of conductive coating providing multiple parallel signal paths for the detection portion of the signal path.

The configuration of FIG. 5f is similar to that of FIG. 5e, except that each of the two segments 105a and 105b is individually connected to a different channel 205a, 205b at the electrical terminal 102 via different local conductive regions 203a, 203b respectively. Therefore, the electrical properties across each of the segments 105a, 105b can be measured separately. For example, when the electrical terminal 102 is configured to measure the voltage or the resistance, then the resistance of each segment 105a, 105b can be compared. If only one resistance changes, then particularly small ruptures can be detected.

The configuration of FIG. 5g is similar to that of FIG. 5c, except that the electrically conductive element comprises two parallel segments 105a, 105b forming the detection portion of the signal path. The segments 105a, 105b are connected to the electrical terminal 102 via corresponding channels 205a, 205b. In addition, the electrically conductive element comprises an additional segment 105c providing the return portion of the signal path, and which is connected to a grounding channel 205c. The grounding channel 205c is further electrically connected to the grounding connection 204b. The segments 105a, 105b, 105c may comprise conductive bands of material, and ruptures in the conduit wall 106 of similar size to the width of the bands are detectable. The sensitivity of the detection is improved by comparing the electrical properties (such as voltage or resistance) measured for each channel.

The configuration of FIG. 5h is similar to that of FIG. 5e, except that the electrically conductive element comprises three segments 105a, 105b, 105c in parallel along the detection portion of the signal path.

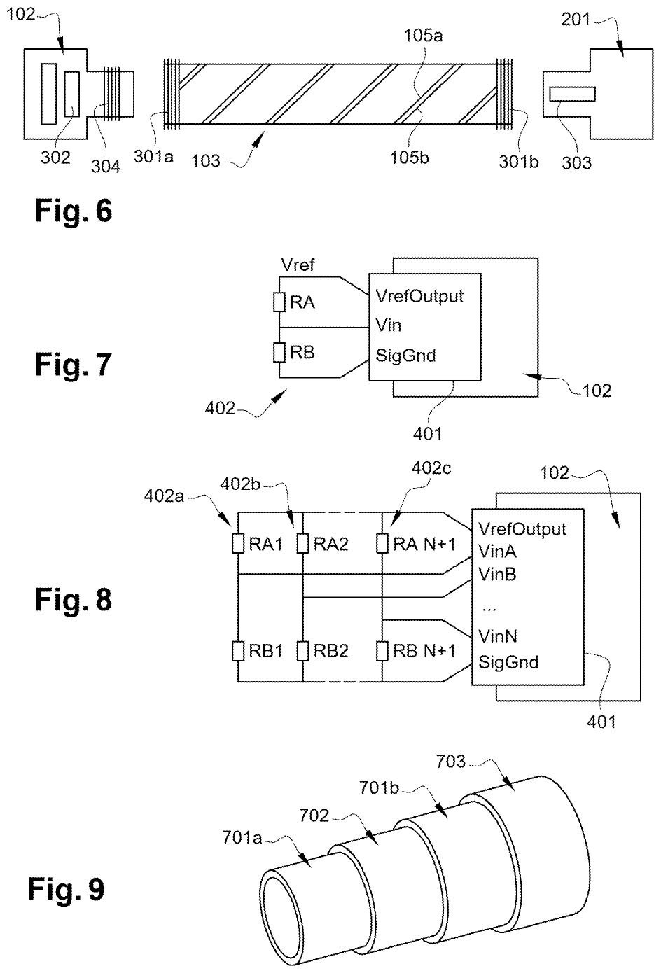

Referring to FIG. 6, a detection system is provided, which system uses a wireless link between the conduit and the electrical terminal and/or the smart connector.

Thus, a detection system is shown, which system may comprise an electrical terminal 102, electrically conductive elements 105a, 105b in the form of coils of wire around a conduit 103, and a remote connector 201. The electrical terminal 102 and the remote connector 201 are located at opposite ends of the conduit 103. The electrically conductive elements 105a, 105b form a coil at regions 301a and 301b proximate the ends of the conduit 103 to provide a wireless transmission via inductive coupling between the conduit 103 and the electrical terminal 102 and/or the remote connector 201.

The inductive coupling coils provide an electrical communication path for transferring radio frequency identification (RFID) frequency data (and power) between an RFID chip 302 located at the electrical terminal 102 and an RFID tag 303 located at the remote connector 201. The coil is preferably resonant at a frequency generated by the RFID chip.

A break/rupture of the conduit 103 may cause a failure in the conductive elements provided along the conduit, thereby disabling or modifying the data signal received from the RFID tag 303 by the RFID chip 302, thereby ensuring a detection of the break. Furthermore, cutting the conduit from the electrical terminal 102 or the remote connector 201 disables the reading of the RFID tag 303, thereby causing an alert.

The conductive element that is part of the conduit is shown as being arranged in a helical manner but it will be noted that other arrangements of conductive elements as described herein may be possible.

Referring to FIG. 7, the electrical terminal 102 may comprise a processing unit in the form of an analog-to-digital converter 401. The analog-to-digital converter 401 may comprise a voltage reference output VrefOutput configured to provide a predetermined voltage, a voltage input Vin and a ground signal input SigGnd. The converter 401 is connected via these inputs/outputs to a bridge circuit 402 which is well known in the state of the art.

The output VrefOutput can be electrically connected to a first branch of the bridge circuit 402 comprising a series resistor RA. The signal SigGnd can be electrically connected, via an electrical ground such as a chassis of a vehicle, to a second branch of the bridge circuit 402 comprising a resistor RB, which corresponds to an electrically conductive element as described above. The input Vin can be connected to a third branch of the bridge circuit 402 which is electrically connected between the ends of the first and second branches. The converter 401 is configured to determine a resistance across the electrically conductive element based on a measurement of the voltage Vin from the third branch of the bridge circuit 402, and the predetermined voltage output VrefOutput. In particular, the input Vin is calculated by the following mathematical equation:

$$V in = RB / ( RA + RB ) \times V ref$$

FIG. 8 shows an example of construction of electrical terminal 102 and circuit that is similar to that described in connection with FIG. 7, however there are multiple resistors RB1, RB2, RBN+1, corresponding to multiple electrically conductive elements, which may correspond to the segments coupled to the conduit as described above, for example with reference to FIGS. 5g and 5h. Each electrically conductive element corresponding to the resistors RB1, RB2, RBN+1 is in series with a second branch of a corresponding bridge circuit 402a, 402b, 402c. Each of the bridge circuits includes a corresponding series resistor on the respective first branch RA1, RA2, RAN+1. Each of the bridge circuits provides a corresponding voltage input VinA, VinB, VinN to be measured by the converter 401. Therefore, the resistors RB1, RB2, RBN+1 can each be monitored separately providing a high level of accuracy for determining ruptures in a conduit as described above.

Referring to FIG. 9, there is shown an alternative embodiment of a detection conduit that can be used in the detection system according to the present disclosure. In this alternative, the conduit 103 comprises two electrically conductive layers 701a, 701b that define first segments for the conductive element 105. An insulating layer 702 is disposed between the electrically conductive layers 701a, 701b. An external layer 703 is disposed outside the conduit 103.

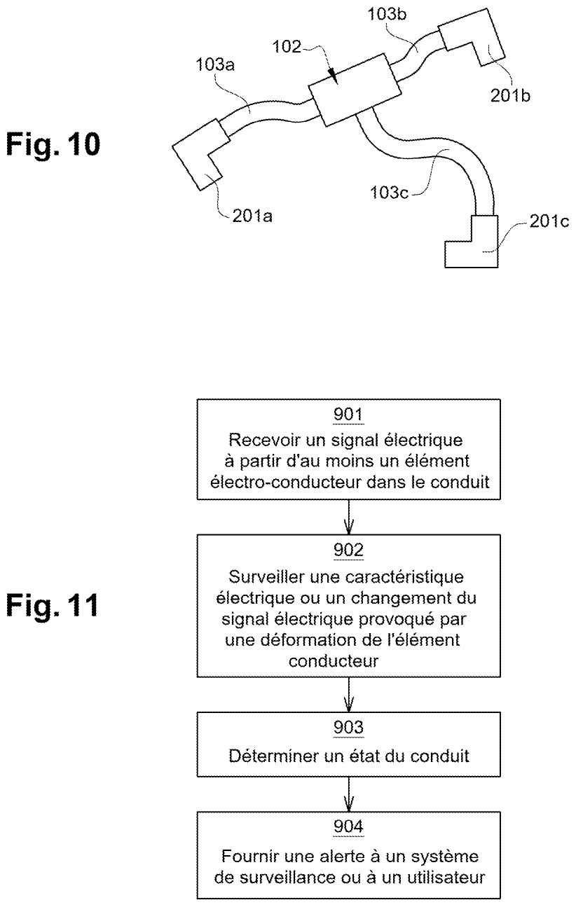

Referring to FIG. 10, a detection system may comprise multiple detection conduits (each as described herein) 103a, 103b, 103c that are each coupled to a central electrical terminal 102, as described herein. Each of the detection conduits 103a, 103b, 103c may be connected to a corresponding remote connector 201a, 201b, 201c. The assembly provides a modular assembly that can be adapted to multiple different types of geometries. A break or cut in any detection conduit 103a, 103b, 103c, may be detected by a single electrical terminal 102, thereby reducing the number of connections/cables, and reducing the installation cost. The assembly shown in FIG. 10 is a radial arrangement but others are possible.

Referring to FIG. 11, a method for operating a detection system according to the present disclosure comprises, at step 901, receiving an electrical signal from at least one electrically conductive element integrated in the conduit and in the connector, and which indicates a state of the conduit and the connector.

At step 902, the electrical signal is monitored for an electrical characteristic or a change in the electrical signal caused by a deformation of the electrically conductive element.

At step 903, a determination may be made as to whether a monitored change indicates a change in the state of the conduit, such as a deformation of the shape of the conduit (such as a rupture), a cut in the conduit, a poor connection of the connector, or a break of the connector.

At step 904, an alert may be provided to a monitoring system or a user.

The alert may correspond to the detected change.

It will be noted that the processing unit described herein that is located locally with respect to the connectors and conduit may simply provide an output signal that represents a change in the monitored state, rather than an alert per se. Thus, the determination of step 903 and the provision of the alert may be performed by a different processing unit that is part of a different system or an overall system of which the detection system is a part.

Detection systems as described herein have been found to operate advantageously, particularly when subjected to external states such as conduit flexure, the presence of water, and elevated temperature—for example 80 degrees C. Where the electrical property being monitored is a resistance across the electrically conductive element, the above-described constructions provide a correlation between a size of the conduit rupture and a resistance level measured by the electrical terminal. It would therefore be possible for a user to use the present system to determine the severity of any rupture or other damage to the conduit.

The detection systems discussed herein are not limited to an application with positive crankcase ventilation systems. Other examples of use include detection, in fluid systems, of fluids critical to battery pack cooling systems, electric motor cooling systems (including system tubes and connectors), hydrogen fuel systems, and hydrogen vehicle cooling systems.

It will be understood that the present disclosure is not limited to the examples and embodiments described above and various modifications and improvements may be made without departing from the concepts described herein. Unless mutually exclusive, any of the features may be used separately or in combination with any other features and the disclosure extends to and includes all combinations and sub-combinations of one or more features described herein.

1. A detection system for detecting a failure in a fluid path of a fluid system, the detection system comprising:
at least one conduit comprising a conduit wall that defines a fluid path for fluid transfer;
at least one connector connected to the at least one conduit, the at least one connector comprising two parts, respectively a female connector and a male connector, removably fixed together, the male connector being secured to the female connector in a connected state of the at least one connector and the male connector being separated at least partially from the female connector in a partially or totally disconnected state of the at least one connector;
a retaining element slidably connected to the at least one connector, the retaining element being movable in an axial direction between a disengaged position, in which it allows relative axial movement between the female connector and the male connector, and an engaged position, in which it prevents relative axial movement between the female connector and the male connector,
a ring arranged between the female connector and the male connector, the ring being held in abutment against the male connector by means of at least one elastic return element exerting a thrust on the ring in a direction tending to move it away from the female connector, the at least one elastic return element being compressed when the at least one connector is in its connected state;
at least one electrically conductive element forming an electrical signal path for an electrical signal which indicates a state of the at least one conduit and/or the at least one connector; and,
an electrical terminal electrically connected to the at least one electrically conductive element such that the electrical signal is transmitted to the electrical terminal via the electrical signal path,
wherein the at least one electrically conductive element comprises at least one first electrically conductive segment secured to the at least one conduit, at least one second electrically conductive segment secured to the at least one connector, at least one third electrically conductive segment secured to the retaining element and at least one fourth electrically conductive segment secured to the ring, the at least one first electrically conductive segment being electrically connected to the at least one second electrically conductive segment, the at least one third electrically conductive segment and the at least one fourth electrically conductive segment in the connected state of the at least one connector and not being electrically connected to the at least one second electrically conductive segment and/or to the at least one third electrically conductive segment and/or to the at least one fourth electrically conductive segment in the partially or totally disconnected state of the at least one connector.

2. The detection system according to claim 1, wherein the at least one second electrically conductive segment comprises at least three separate portions, respectively a first portion and a second portion extending axially along an external wall of the female connector and a third portion extending circumferentially around the external wall.

3. The detection system according to claim 2, wherein the at least one third electrically conductive segment is in contact with the first and third portions of the at least one second electrically conductive segment in the engaged position of the retaining element and not being in contact with the third portion in the disengaged position of the retaining element.

4. The detection system according to claim 2, wherein the at least one fourth electrically conductive segment is in contact with the second and third portions of the at least one second electrically conductive segment in the connected state of the at least one connector and not being in contact with the second portion in the partially or totally disconnected state of the at least one connector.

5. The detection system according to claim 1, wherein the at least one elastic return element is integral with the ring and comprises two elastic blades of curved shape extending along two opposite sides of the ring, the two elastic blades being deformed when the ring is compressed between the male connector and the female connector when the at least one connector is in the connected state.

6. The detection system according to claim 1, wherein the ring comprises two straight tabs extending along two opposite sides of the ring, at least one of the straight tabs supporting at its free end the at least one fourth electrically conductive segment.

7. The detection system according to claim 1, further comprising a processing unit for receiving the electrical signal and monitoring the electrical signal for an electrical characteristic that indicates a failure of the at least one conduit and/or a partial or total disconnection of the at least one connector respectively, the processing unit being configured to determine that a failure is present in the at least one conduit or that the at least one connector is totally or partially disconnected using the monitored electrical characteristic.

8. The detection system according to claim 7, wherein the electrical characteristic is one or more characteristics selected from the group consisting of voltage, resistance, conductance, capacitance, inductance, frequency response, amplitude or transit time, or a change thereof.

9. The detection system according to claim 1, wherein the at least one first electrically conductive segment extends over the entire length of at least one conduit.

10. The detection system according to claim 1, wherein at least one first electrically conductive segment extends circumferentially around a surface of the conduit wall of the at least one conduit.

11. The detection system according to claim 1, wherein at least one first electrically conductive segment is at least partially integrated into the conduit wall and/or provides an external or internal surface of the at least one conduit.

12. The detection system according to claim 1, wherein the at least one electrically conductive element comprises one or more conductive layer(s), tape(s), film(s), wire(s), braid(s) or a conductive polymer.

13. The detection system according to claim 1, wherein the at least one first electrically conductive segment secured to the at least one conduit is covered with a coating or a special material protecting the electrical signal from external electromagnetic influences present in a vehicle.

14. A vehicle comprising the detection system according to claim 1.

15. A method for detecting a state of a fluid system using the detection system according to claim 1, and comprising the steps of:
receiving an electrical signal from at least one electrically conductive element;
monitoring the electrical signal for an electrical characteristic that indicates a failure of the at least one conduit and/or a failure or disconnection of the at least one connector; and
determining a failure in the fluid path of the fluid system based on the monitored electrical characteristic.

16. The method of claim 15, wherein the electrical characteristic is one or more characteristics selected from the group consisting of: voltage, resistance, conductance, capacitance, inductance, frequency response, amplitude or transit time, or a change thereof.

17. The detection system according to claim 3, wherein the at least one fourth electrically conductive segment is in contact with the second and third portions of the at least one second electrically conductive segment in the connected state of the at least one connector and not being in contact with the second portion in the partially or totally disconnected state of the at least one connector.

18. The detection system according to claim 17, wherein the at least one elastic return element is integral with the ring and comprises two elastic blades of curved shape extending along two opposite sides of the ring, the two elastic blades being deformed when the ring is compressed between the male connector and the female connector when the at least one connector is in the connected state.

19. The detection system according to claim 18, wherein the ring comprises two straight tabs extending along two opposite sides of the ring, at least one of the straight tabs supporting at its free end the at least one fourth electrically conductive segment.

20. The detection system according to claim 19, further comprising a processing unit for receiving the electrical signal and monitoring the electrical signal for an electrical characteristic that indicates a failure of the at least one conduit and/or a partial or total disconnection of the at least one connector respectively, the processing unit being configured to determine that a failure is present in the at least one conduit or that the at least one connector is totally or partially disconnected using the monitored electrical characteristic.
